(19) United States
(12) Patent Application Publication
(10) Pub. No.: US 2026/0271194 A1
(43) Pub. Date: Sep. 10, 2026

(54) COMPONENT COVERS INHIBITING DYNAMIC COMPONENT WARPING DURING REFLOW

(71) Applicant: INTERNATIONAL BUSINESS MACHINES CORPORATION, Armonk, NY (US)

(72) Inventors: Mert KARAKAS, Rochester, MN (US); Emma QUINN, Rochester, MN (US); Logan BISTODEAU, Rochester, MN (US); Angelina ALEXOPOULOS, Rochester, MN (US); Mark K. HOFFMEYER, Rochester, MN (US); Theron Lee LEWIS, Rochester, MN (US)

(21) Appl. No.: 19/074,542

(22) Filed: Mar. 10, 2025

(51) Int. Cl. H05K 3/34; H05K 1/02; H05K 1/18

(52) U.S. Cl. CPC H05K 3/3494; H05K 1/0271; H05K 1/181; H05K 2201/0308; H05K 2201/10393; H05K 2201/10734; H05K 2203/0195

(57) ABSTRACT

A method is provided for inhibiting dynamic component warping during a circuit board reflow process. The method includes obtaining a cover for a component of a circuit board, where the cover includes a shape memory alloy structure configured to inhibit warping of the component during the reflow process. Further, the method includes coupling the cover to the component of the circuit board to form a covered component. The coupling ensures that, with reaching of a transition energy threshold during the reflow process, the shape memory alloy structure of the cover generates, based on a shape memory alloy transition, a force in a direction to inhibit the warping of the component during the reflow process.

### BACKGROUND

The present invention relates generally to circuit boards, such as printed circuit board assemblies (PCBAs), and more particularly, to circuit boards and attached components, including socket connectors, fabricated using a soldering process known as reflow.

Printed circuit board assemblies (PCBAs) having a variety of electrical components are widely used in the electronics industry in products including computers, servers, televisions, telecommunication devices, and other electronic devices. During circuit board assembly of components, which can include, for instance, microprocessor central processing units (CPUs), secondary printed circuit board assemblies (sometimes referred to as daughter cards), graphics processing units (GPUs) and other electronic components, the components are mechanically and electrically coupled to a primary printed circuit board (such as a mother board). The board assembly process involves conditions that can result in component and/or board warpage during the process. The components often are attached via a component attachment structure, such as via solder, to a coplanar surface on the printed circuit board, and consequently any component and/or board warping during the process can result in a solder defect.

For instance, solder defects can occur in the form of head-in-pillow (HIP) defects because of differences in thermodynamic warpage between one or more components and the printed circuit board (PCB) during a reflow process, largely due to the different coefficients of thermal expansion (CTE) of materials within the components and the printed circuit board. This is especially true for socket connector systems, such as hybrid land grid array (LGA) socket connector systems, hybrid ball grid array (BGA) socket connector systems, etc., due to complex shapes in the molded housing and the PCB warpage interactions. This is an industry wide issue that affects a variety of products and devices, such as server backplanes, where socketed high performance modules are used.

### SUMMARY

Certain shortcomings of the prior art are overcome, and additional advantages are provided herein through the provision of a method which includes obtaining a cover for a component of a circuit board. The cover includes a shape memory alloy structure configured to inhibit warping of the component during a reflow process. In addition, the method includes coupling the cover to the component of the circuit board to form a covered component, where the coupling ensures that, with reaching of a transition energy threshold during the reflow process, the shape memory alloy structure of the cover generates, based on a shape memory alloy transition, a force in a direction to inhibit the warping of the component during the reflow process.

In another aspect, a method is provided which includes obtaining a cover for a component of a circuit board. The cover includes multiple shape memory alloy structures configured to inhibit warping of the component during a reflow process. In addition, the method includes coupling the cover to the component of the circuit board to form a covered component. The coupling ensures that with reaching of a transition energy threshold during the reflow process, the multiple shape memory alloy structures of the covered component generate, based on a shape memory alloy transition, a force in a direction to inhibit the warping of the component during the reflow process.

In a further aspect, a component cover is provided which includes a rigid structure and a shape memory alloy structure attached to the rigid structure. The shape memory alloy structure is configured to inhibit a warping of a component of a circuit board during a reflow process, with the component cover coupled to the component, by generating, based on a shape memory alloy transition with reaching a transition energy threshold, a force in a direction to inhibit the warping of the component during the reflow process.

Additional features and advantages are realized through the structures and techniques described herein. Other embodiments and aspects are described in detail herein and are considered a part of the disclosed inventive aspects.

### BRIEF DESCRIPTION OF THE DRAWINGS

One or more aspects are particularly pointed out and distinctly claimed as examples in the claims at the conclusion of the specification. The foregoing and objects, features, and advantages of one or more aspects are apparent from the following detailed description taken in conjunction with the accompanying drawings in which:

FIG. 1A depicts a plan view of one embodiment of a covered component of a circuit board, which can include and/or use one or more aspects of the present disclosure;

FIG. 1B is an elevational view of the covered component of FIG. 1A, showing a standard cover which is replaced for reflow, in accordance with one or more aspects of the present disclosure;

FIG. 1C is a partial cross-sectional view of the covered component of FIG. 1B, taken along line 1C-1C thereof, showing a coupling structure which can also be used by a reflow cover (or cover) to couple to the component, in accordance with one or more aspects of the present disclosure;

FIGS. 2A-2C are elevational depictions of dynamic component wrapping on a circuit board during reflow, which is addressed by the use of a reflow cover, in accordance with one or more aspects of the present disclosure;

FIG. 3A depicts one embodiment of a covered component on a circuit board, where the covered component includes a cover, or reflow cover, with a shape memory alloy structure, in accordance with one or more aspects of the present disclosure;

FIG. 3B depicts the covered component and circuit board of FIG. 3A, with a rigid structure portion of the cover shown in exploded view to illustrate one embodiment of a shape memory alloy structure of the cover, in accordance with one or more aspects of the present disclosure;

FIG. 3C is an enlarged view of one embodiment of a cover of the covered component of FIGS. 3A-3B, and showing one embodiment for attaching together the shape memory alloy structure and rigid structure of the cover, in accordance with one or more aspects of the present disclosure;

FIG. 3D depicts one embodiment of the rigid structure of a cover, such as the cover of FIGS. 3A-3C, shown with a rib extending down from the underside of the rigid structure, in accordance with one or more aspects of the present disclosure;

FIGS. 4A-4C are elevational views of one embodiment of a circuit board reflow process using the covered component of FIGS. 3A-3C, in accordance with one or more aspects of the present disclosure;

FIG. 5A depicts another embodiment of a covered component positioned on a circuit board, where the covered component includes a cover, or reflow cover, with multiple shape memory alloy structures, in accordance with one or more aspects of the present disclosure;

FIG. 5B is a partially enlarged view of the covered component of FIG. 5A, depicting one embodiment of the shape memory alloy structures attached at the corners of the cover, in accordance with one or more aspects of the present disclosure;

FIG. 5C depicts one embodiment of the rigid structure of a cover, such as the cover of FIGS. 5A-5B, shown with a rib extending down from the underside of the rigid structure, in accordance with one or more aspects of the present disclosure;

FIGS. 6A-6D depict elevational views of one embodiment of a circuit board reflow process using the covered component of FIG. 5A-5C, in accordance with one or more aspects of the present disclosure; and

FIG. 7 depicts one embodiment of a circuit board reflow process using a covered component, such as the covered component of FIGS. 3A-3D and/or the covered component of FIGS. 5A-5C, in accordance with one or more aspects of the present disclosure.

### DETAILED DESCRIPTION

Aspects of the present disclosure with certain features, advantages and details thereof are explained more fully below with reference to the non-limiting example(s) illustrated in the accompanying drawings. Descriptions of well-known systems, devices, processing techniques, etc., are omitted so as to not unnecessarily obscure the disclosure in detail. It should be understood, however, that the detailed description and the specific example(s), while indicating aspects of the disclosure, are given by way of example only, and are not by way of limitation. Various substitutions, modifications, additions, and/or arrangements, within the spirit and/or scope of the underlining inventive concept will be apparent to those skilled in the art for this disclosure. Note further that reference is made below to the drawings, where the same or similar reference numbers used throughout different figures designate the same or similar components. Also, note that numerous inventive aspects and features are disclosed herein, and unless otherwise inconsistent, each disclosed aspect or feature is combinable with any other disclosed aspect or feature as desired for a particular application of the concepts disclosed.

The illustrated embodiments are described below using specific designs, architectures, layouts, schematics, or tools only as examples, and the disclosed invention is not limited to the illustrated embodiments. Furthermore, the illustrative embodiments may be described in certain instances using particular tools, and processing environments only as example for clarity of description. The illustrative embodiments can be used in conjunction with other comparable or similarly purposed structures, systems, applications, or architectures.

In general, the embodiments disclosed herein present methods and structures for inhibiting (e.g., preventing or countering) warping of a component, such as a socket or socket connector system, of a circuit board during a reflow process of the circuit board. Advantageously, an electronic system produced according to the processes and structures discussed herein has improved reliability over a range of operating conditions due, for instance, to the quality of the resultant component attachment structures.

For the purposes of discussion, a “component” can be an electronic package that includes a planar array of connection points used to make connections to a corresponding area on a circuit board, such as a printed circuit (PC) board. Connecting structures are used to create connections that are both electrical and mechanical between the component and circuit board. The connecting structures can include ball grid array (BGA) solder balls, land-grid array (LGA) structures, hybrid LGA (HLGA) structures, solder columns, and other electrical and mechanical interconnects such as springs, pogo-pins, elastomeric materials, etc. A component can also include, or be, a socket, socket connector or socket assembly, etc., that makes use of one or more of the above-noted connecting structures. It should be understood that the principles of the invention can apply to a wide range of types of components and circuit boards. The sockets and boards illustrated and described herein represent one embodiment only of the types of components and boards to which principles of the invention apply.

In one or more implementations, the particular types of electronic connect components relevant to certain embodiments disclosed herein are known as “area array devices”, which include a dense array of conductive sites on a substantially planar surface designed to mate with a corresponding set of sites on a circuit board. This type of component often includes a laminate substrate which provides one substantially planar surface for the purpose of active or passive electronic device attachment, and an opposite substantially planar surface for an array of mating conductive sites. Note that a substantially planar surface is planar within the normal process tolerances of semiconductor package and circuit board processing facilities. An exemplary flatness specification may be 0.004 inches (4 mils) on a device 2 inches or larger per side, however this can vary depending on manufacturing methods and connection type(s).

A ball grid array (BGA) substrate is a type of area array device (package) used in conjunction with complex integrated circuits (ICs), which can provide a large number and high density of electrical connections. Multiple electrical and mechanical connections are formed between, for instance, the BGA substrate and circuit board by partially melting (reflowing) soler balls previously attached to metal pads on the substrate. BGA packages with hundreds, and even thousands, of solder ball connections are commercially available.

Increasingly complex integrated circuits (ICs or chips) require greater numbers of electrical connections on the chip packages they are mounted on in order to meet the IC's signal input output (IO) and power needs. A socket (or chip package) acts as an intermediate electrically conductive layer between the chip and the circuit board and provides multiple electrical attachment points for connection to the circuit board. As noted, a socket is one example of a component.

A circuit board is generally understood to be a rigid planar laminate structure, that includes one or more insulating or dielectric layers and one or more conductive layers, and which provides one or more surfaces on which to mount electronic components, and a means to interconnect the components.

The characteristics of a circuit board, such as a printed circuit board, module, etc., that apply to the embodiments are rigidity and at least one planar surface which contains an array of contact sites which form a mating pattern to those found on the opposing surface of a component. The contact sites are used to make electrical and mechanical connections to the component.

The footprint dimensions of large ball-count BGA packages (i.e., one embodiment of a component) can be greater than 50 mm×50 mm. Solder balls attached to BGA substrates have a generally spherical shape prior to a reflow operation. An industry trend of decreasing solder ball diameter to accommodate smaller solder ball pitches has resulted over time in decreasing spacing between the BGA module and the circuit board.

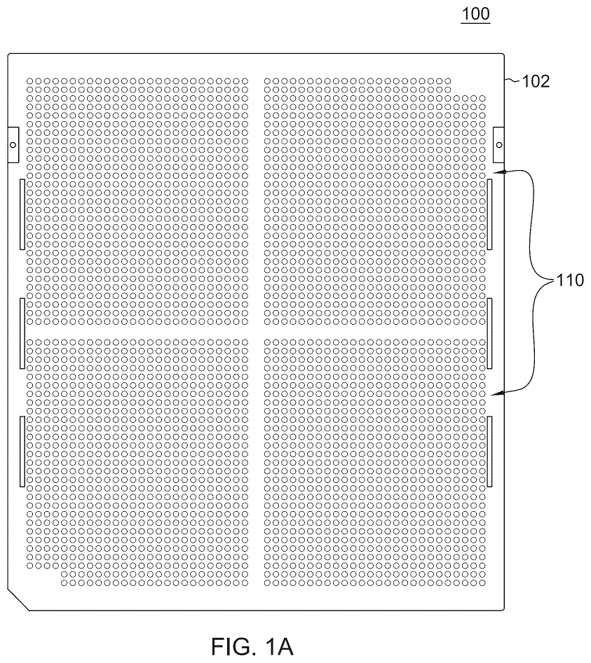

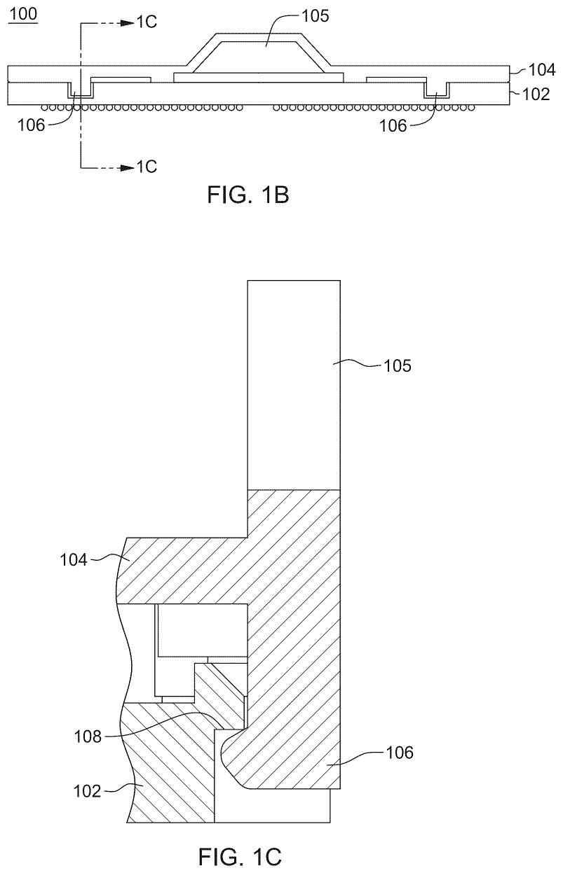

By way of example, FIGS. 1A-1C depict one embodiment of a component assembly 100, such as a socket assembly, that can be coupled or affixed to a circuit board, such as a printed circuit board (PCB), and which can include and/or use one or more aspects of the present disclosure. In FIGS. 1A-1C, one embodiment of a component assembly 100 is illustrated, which includes by way of example, a hybrid land grid array (LGA) socket connector system having a component or socket 102 (e.g., socket connector) with a land grid array of metal contacts (not shown) on one side, and one or more ball grid arrays (BGAs) of solder balls 110 on another side to, for instance, attach the socket to a circuit board, in one or more embodiments. In the embodiment of FIGS. 1A-1C, component assembly 100 also includes a mating cover 104 (e.g., a standard socket cover) coupled to socket 102 by multiple edge fasteners 106, which as shown in FIG. 1C couple or clip below a lip or edge 108 formed in socket 102 to which the connecting fasteners 106 of the cover align. In one or more embodiments, mating cover 104 can include one or more raised handle portions 105, by way of example only, and can be a standard socket cover coupled to socket 102 to, for instance, protect the upper surface contacts of the socket during the circuit board assembly process.

The ball grid array (BGA) interface area on both the socket, or BGA package, and the circuit board are planar at room temperature and the trend of decreasing spacing between them has made the BGA to circuit board interface susceptible to defects caused by planar deviations such as warp. Even a slight amount of warp mismatch between the component and the board can result in defects in the BGA interfaces, which are important in providing stable electrical and mechanical connections between the component and circuit board.

Electronic packages and circuit boards are typically constructed from a laminate of materials which can include various conductor and dielectric layers, each material type having its own unique coefficient of thermal expansion (CTE). When heated, each material type can expand at a different rate, potentially causing warping of the component attached to the circuit board and/or warping of the circuit board.

One design methodology for electronic packages and circuit boards involves using a vertical arrangement of conductor and dielectric layers (stackup) that is symmetrical about an axis drawn through the center of a cross section of the laminate layers, and parallel to the layers. Aspects of the symmetry include the number, arrangement, thicknesses and types of layers on each side of the axis of symmetry.

A symmetrical stackup can minimize or eliminate warping of the circuit board or package during assembly operations involving temperature excursions, such as a reflow process. Design or manufacturing constraints, however, can prohibit the stackup from being entirely symmetrical, and some warping of either the component or the circuit board, or both, can occur as a result.

Warping has two significant attributes; phase (or direction) and magnitude. With respect to the component, the warp phase refers to the direction (upwards or downwards from a reference plane) of component deflection. Warp magnitude is defined as the largest vertical component deflection that can be measured relative to a reference plane, often a flat surface. Warp magnitude can be measured within the field of BGA connection pads on the circuit board or component surface.

Dynamic (thermally induced) warp is the deformation of a component (e.g., socket or chip package) or a circuit board, as it experiences a thermal excursion, for example during a reflow process. A component can have a certain cross-sectional profile at room temperature, then deflect (movement of edges and/or surfaces) a certain amount either upwards (concave) or downwards (convex) during heating, then return to the original profile once it returns to room temperature. Concave deflection has a positive 2^{nd} derivative as seen from a side view, such as a “cup” shape. Convex deflection has a negative 2^{nd} derivative as seen from a side view, such as a “cap” shape. Dynamic warp can be exacerbated with larger component footprints and PC board mounting area.

The dynamic warp of a circuit board and a component attached to it during a reflow operation can be different (mismatched) in phase or magnitude, and a number of types of BGA reflow defects that can occur can later result in mechanical or electrical failures. Defects can occur when one or more solder balls on the BGA substrate separate from the solder paste during a reflow operation, due to mismatch between the circuit board and component dynamic warp characteristics. Exemplary warp magnitudes of a component can be between 0.254 mm and 0.508 mm, though higher magnitudes are possible. An exemplary maximum permissible package warpage may range from 0.10 mm to 0.25 mm, depending on the solder ball size and manufacturing process used.

One type of defect, known as a “head-in-pillow” defect, occurs when BGA substrate solder balls are separated from the solder paste on the circuit board during a reflow process due to dynamic warp mismatch. Solder paste typically contains flux, a chemical agent to clean and prevent oxidation of mating metallic surfaces during the reflow process. When a solder ball is separated from contact with the solder paste during the heating of a reflow operation, the lack of flux can allow an oxide layer to be grown on the outer surface of the solder ball. This oxide layer can subsequently prevent proper bonding of the solder ball to the solder paste, resulting in a defective (weak) mechanical connection.

Defects such as the head-in-pillow type defect can manifest themselves immediately, as an intermittent or open, or can be latent, only appearing after some period of thermal cycling of the component and circuit board assembly. Because a head-in-pillow defect can initially appear as a valid connection, it cannot be easily detected using classical test methods. The latent failure of a single BGA connection can result in catastrophic system failure, as every signal connection can be important to the resultant electronic system(s).

A material's coefficient of thermal expansion (CTE) is defined as the change of unit length per change in unit temperature for that type of material. A commonly used unit of measure for CTE is parts-per-million per degree Celsius (ppm/° C.). A material can expand or contract linearly in proportion to the CTE times the change in temperature experienced. A larger CTE indicates a greater material expansion than a smaller CTE, for an identical temperature excursion. The dynamic warp of a component (or a circuit board) is largely dependent on the CTEs, dimensions, and arrangement of the various materials of the laminate structure. Dynamic warp and dynamic warp mismatch can also be influenced by temperature gradients across a component (or a circuit board), due to uneven heating during a reflow operation.

For simplicity of illustration, the figures depict a BGA attached component, such as a socket, and its relationship to an exemplary circuit board; however, the principles of this disclosure can be applied to other types of components and circuit boards or other rigid structures.

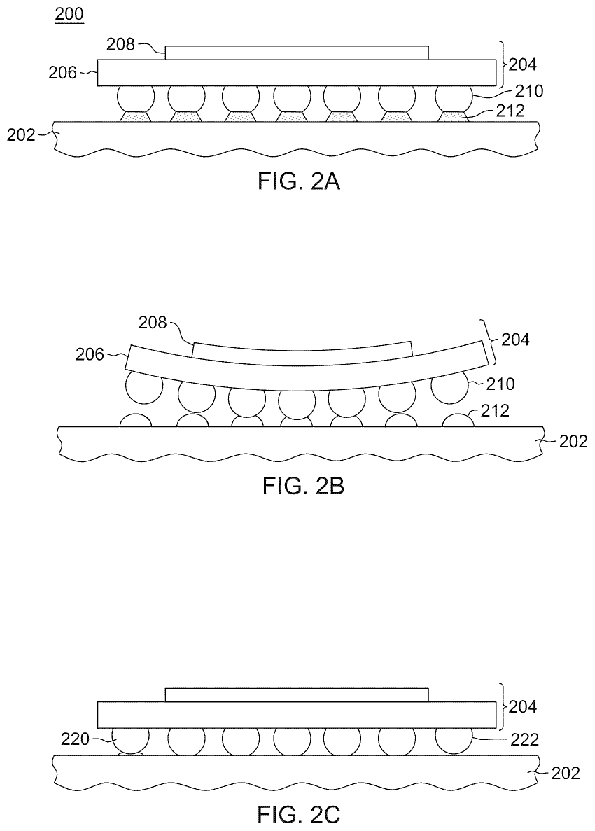

By way of example, FIGS. 2A-2C are cross-sectional elevational depictions of one embodiment of a circuit board assembly 200 undergoing reflow processing. As illustrated, circuit board assembly 200 includes a circuit board 202 with a component 204, such as a hybrid socket, to be electrically and mechanically attached to circuit board 202 via an array of electrical interconnects, such as a ball grid array of solder connections 210, where the solder connections 210 couple, in one embodiment, during reflow using a solder paste 212 to circuit board 202. FIG. 2A depicts one embodiment of the circuit board assembly during ramp up of the reflow process. Note in this regard that the component and/or circuit board can have an initial warpage condition (not shown), and that the component (e.g., hybrid socket) and circuit board can often warp in opposite directions as they are exposed to soldering temperatures (i.e., the reflow process temperatures). During reflow, as temperature (or heat energy) increases, the component can warp relative to the circuit board, as illustrated in FIG. 2B, causing one or more of the solder connections 210 to pull away from the circuit board 202. By way of example, during the reflow process, a maximum warping of the component relative to the circuit board can occur, for instance, at a temperature of 200° C. or greater. In one or more embodiments, this warping can be highest at the corners and edges of the component, as illustrated in FIG. 2B. In situations where the component warping is excessive, one or more defects can form upon cool down of the circuit board assembly to room temperature, such as illustrated in FIG. 2C. For instance, in one or more embodiments, one or more head-in-pillow defects 220 can form at one or more of the solder interconnects, and/or one or more of the solder interconnects 222 can potentially be open circuited, that is, not making electrical contact with the circuit board.

As noted, a head-in-pillow type defect is where a solder ball does not make a metal bond to the solder or solder paste on the circuit board. For instance, in practice a hybrid socket ball grid array (BGA) connector system can warp, resulting in changes in coplanarity and flux activity. In one embodiment, where socket coplanarity at room temperature is 8 mils, the socket connector body can warp through reflow processing by as much as 8 mils, with the corners or edges pulling up away from the circuit board. The head-in-pillow type defects skew to the socket corners and edges, with the socket being at maximum warp at peak reflow. Any exposed solder surfaces continue to oxidize with potentially the flux becoming fully reacted. Molten solder surfaces are coated with reacted flux and/or oxide residues. On cooling, the socket starts returning towards (e.g., warping back) the board surface, however, some head-in-pillow defects can remain, while others may heal as the socket comes back into coplanarity with the circuit board.

Disclosed herein are component covers and methods to inhibit dynamic component warping during the reflow processing, and in particular, to inhibit dynamic component warpage during a circuit board reflow. In one or more embodiments, the method includes obtaining a cover (or reflow cover) for a component of a circuit board, where the cover includes a shape memory alloy structure configured to inhibit warping of the component during the reflow process. In addition, the method includes coupling the cover to the component to the circuit board to form a covered component, where the coupling ensures that, with reaching a transition energy threshold during the reflow process, the shape memory alloy structure of the cover generates, based on a shape memory alloy transition, a force in a direction to inhibit the warping of the component during the reflow process.

In one or more other embodiments, the method includes obtaining a cover for a component of a circuit board, where the cover includes multiple shape memory alloy structures configured to inhibit warping of the component during the reflow process. In addition, the method includes coupling the cover to the component of the circuit board to form a covered component, where the coupling ensures that with reaching of a transition energy threshold during the reflow process, the multiple shape memory alloy structures of the cover generate, based on a shape memory alloy transition, a force in a direction to inhibit the warping of the component during the reflow process.

In one or more embodiments, the cover is a component cover, or reflow cover, which includes a rigid structure and a shape memory alloy structure attached to the rigid structure. The shape memory alloy structure is configured to inhibit warping of a component of a circuit board during a reflow process, with the cover coupled to the component, by generating based on the shape memory alloy transition with reaching of a transition energy threshold, a force in a direction to inhibit the warping of the component during the reflow process.

Additional features and aspects of the above-noted embodiments are also disclosed herein. For instance, in one or more embodiments, the component is a hybrid land grid array (LGA) socket, and the cover (or reflow cover) is configured to inhibit or prevent warpage of the hybrid LGA socket during circuit board assembly reflow. As described herein, the embodiments disclosed embody or include, two manufacturing options, that is, a lower-cost consumable cover, and a reusable cover intended for volume manufacturing production, such as for an investment for a fabrication program life cycle. As described herein, the cover has a designed in socket warp mitigation feature during reflow, and the cover is advantageously compatible with current architectures, and avoids the need for additional fixtures and/or use of any adhesives to anchor the component to the circuit board for reflow. Advantageously, the embodiments disclosed can be used in conjunction with legacy circuit boards and components to mitigate warp movement during a reflow process. Further, in one or more embodiments, the cover does not directly attach to any aspect of the circuit board and, for instance, does not require reconfiguring of the component to which the cover attaches. For instance, there is no need to add a shape memory alloy material inside of the component itself. Advantageously, the shape memory alloys described herein operate within the standard reflow cycle temperatures by transitioning during ramp up of the reflow temperature to, for instance, inhibit warping of the component during the reflow process. Further, in one or more embodiments, the shape memory alloy can be selected to transition below the flux activation temperature, in addition to transitioning below the reflow temperature. For instance, in one or more embodiments, the flux activation temperature might be about 100° C., and the solder reflow temperature greater then 200° C., with the shape memory alloy transitioning occurring, for instance, below 100° C.

As disclosed herein, the shape memory alloy structure can be one or more shape memory alloy structures integrated within, or provided as part of, the cover, such as being attached to a rigid structure of the cover. In one or more embodiments, the rigid structure can be, for instance, a forged carbon, carbon-reinforced material, and/or a high performance thermoplastic material, such as a liquid crystal polymer (LCP) composite, by way of example only. The shape memory alloy structure can attach to the rigid structure using a variety of approaches, such as via rivets, heat staking (or thermoplastic staking), and/or an adhesive, again by way of example only.

In embodiments, the shape memory alloy structure is formed of a shape memory alloy (also referred to as smart metal, memory metal, smart alloy, etc.) that remembers its original shape and that, when deformed, returns to a pre-deformed shape when a transition energy threshold is applied to it. Depending on the alloy, the transition energy threshold can be a heat energy transition level or magnetic energy transition level. For instance, for magnetic smart metals, which are a group of alloys that react to magnetic fields, the reflow process can include the application of a magnetic field to the circuit board assembly to transition the shape memory alloy. The most prevalent shape memory alloy materials are copper—aluminum—nickel and nickel titanium, but shape memory alloys can be created by alloying, for instance, zinc, copper, gold and iron. In general, the shape memory alloy material is a memory metal alloy that has an original crystal structure, and when the material is deformed, it causes a different crystal structure to form. Depending on the alloy, heat energy or magnetic energy is applied, and the material returns to its original crystal structure. Unlike most crystal changes in metals, this crystal change does not require diffusion. The “memorized geometry” can be modified by fixating the desired geometry and subjecting it to a thermal treatment, for example a wire can be taught to memorize the shape of a coil spring. The shape memory alloy material can have different shape-memory effects, with the two common effects being a one-way shape memory alloy effect and a two-way shape memory alloy effect. For a one-way shape memory alloy, the shape memory alloy is in its cold state (e.g., below Aₛ, where Aₛ is the temperature at which the transformation from martensite to austenite starts), and the alloy can be bent or stretch, and it will hold those shapes until heated to, or above, the transition energy threshold (e.g., the transition temperature). Upon heating, the alloy transitions to its original shape, and when the metal cools again, it will retain the original shape, that is, until deformed again. The two-way shape memory alloy effect is the effect where the material remembers two different shapes, that is, one at low temperatures, and one at the high temperature. A material that shows a shape-memory effect during both heating and cooling is said to have a two-way shape memory. As disclosed herein, the shape memory alloy structure of the cover (or reflow cover) can have, or include, a one-way shape memory alloy effect or a two-way shape memory alloy effect.

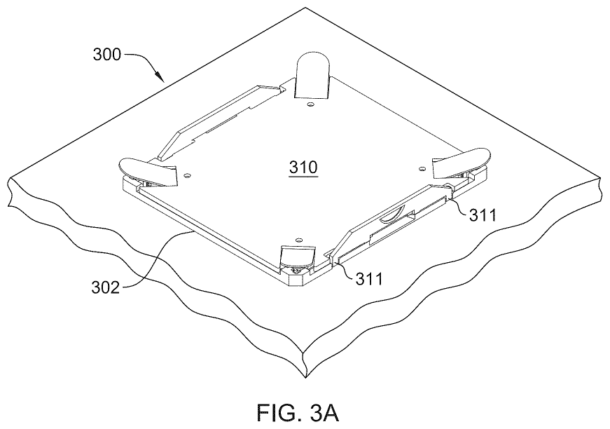

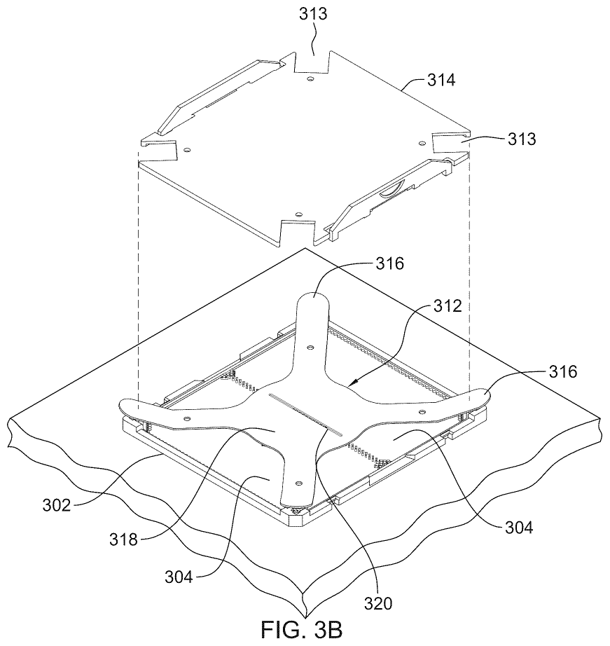

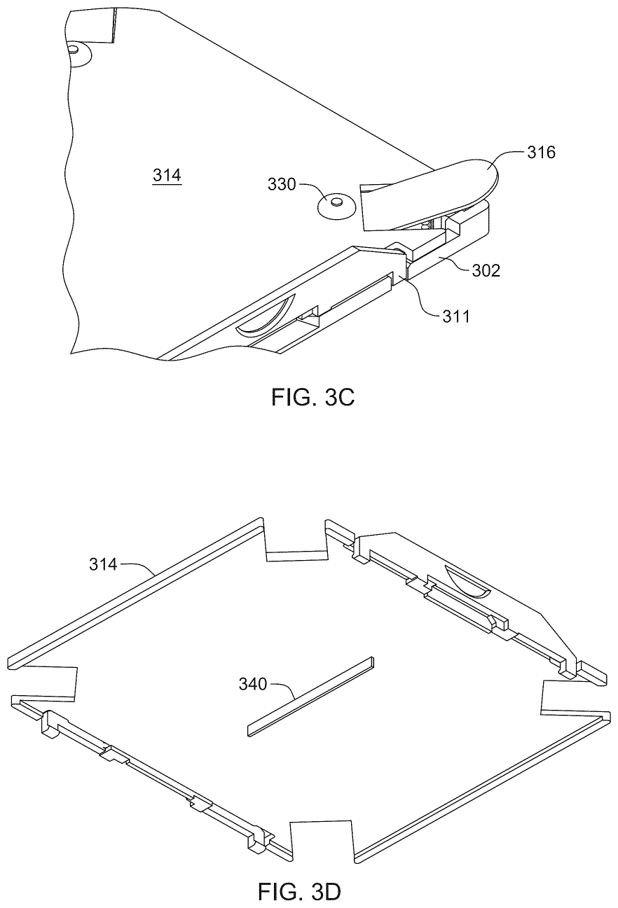

FIGS. 3A-3D depict one embodiment of a covered component on a circuit board 300, where the cover component includes a cover 310 with a shape memory alloy structure 312 (FIG. 3B), in accordance with one or more aspects of the present disclosure. In one or more embodiments, the shape memory alloy structure 312 is fabricated from a shape memory alloy (e.g., smart metal, memory metal, smart alloy, etc.) as described herein. For instance, in one or more embodiments, the shape memory alloy is a copper—aluminum—nickel or nickel titanium alloy, by way of example only. As noted herein, the shape memory alloy material can have different shape memory effects, including a one-way shape memory alloy effect or a two-way shape memory alloy effect, as described.

In the embodiment(s) of FIGS. 3A-3D, circuit board 300 is illustrated with a component 302 positioned on a planar surface of the circuit board. In the embodiment depicted, component 302 is illustrated as a socket, such as a hybrid land grid array (LGA) socket connector, which in one embodiment, includes a ball grid array (not shown) to connect component 302 to the circuit board 300, as well as, for instance, a land grid array 304 on an upper surface of component 302 (see FIG. 3B). In embodiments, cover 310 is configured to fasten or clip, via multiple fasteners 311 to component 302, to couple or fasten the cover to the component such as for a reflow process, as described herein.

In embodiments, shape memory alloy structure 312 of cover 310 is coupled to a rigid structure 314. In one or more embodiments, rigid structure 314 can be formed of, for instance, a forged carbon, carbon-reinforced material, and/or high performance thermoplastic material, such as a liquid crystal polymer (LCP) composite, by way of example only. In the embodiment depicted, rigid structure 314 includes openings or cutouts 313 at the corners of the structure to accommodate respective shape memory alloy tabs 316 which extend, by way of example, from a central portion 318 of shape memory alloy structure 312. In one or more embodiments, shape memory alloy tabs 316 are formed or preformed, to extend at a desired upward angle from central portion 318 at room temperature (and thus, to angle upwards from the component edges when the cover is attached to the component). As noted, shape memory alloy structure 312 can attach to rigid structure 314 via any one of a variety of fasteners, such as rivets, heat staking, adhesive, etc. In the partial, enlarged depiction of FIG. 3C, the cover component of FIGS. 3A-3B, is shown with rivets 330 securing rigid structure 314 and shape memory alloy structure 312 (see FIGS. 3A-3B) together. As noted, and as illustrated in FIGS. 3A & 3C, in one or more embodiments, shape memory alloy tabs 316 can be configured to extend at a desired angle upwards from component 302 at room temperature prior to starting the reflow process. Further, in the embodiment of FIGS. 3A & 3C, fasteners 311 are depicted, which can be similar in design, construction and operation to fasteners 106 described above in connection with FIGS. 1A-1C. Fasteners 311 are provided to couple cover 310 to component 302 for the circuit board assembly reflow process, as described herein. In one or more embodiments, fasteners 311 can be further reinforced latching features for robust cover retention during the reflow process.

In one or more embodiments, shape memory alloy structure 312 can include an opening 320 in central portion 318 configured to accommodate a rib 340 extending from rigid structure 314 towards component 302. FIG. 3D depicts one embodiment of rib 340 sized and configured to reside, for instance, between main contact arrays on an opposing surface of the component 302 (e.g., socket) with coupling of cover 310 to component 302 on the circuit board 300. Rib 340 can be sized and configured to inhibit a convex deformation of the socket during the reflow process, in one or more embodiments.

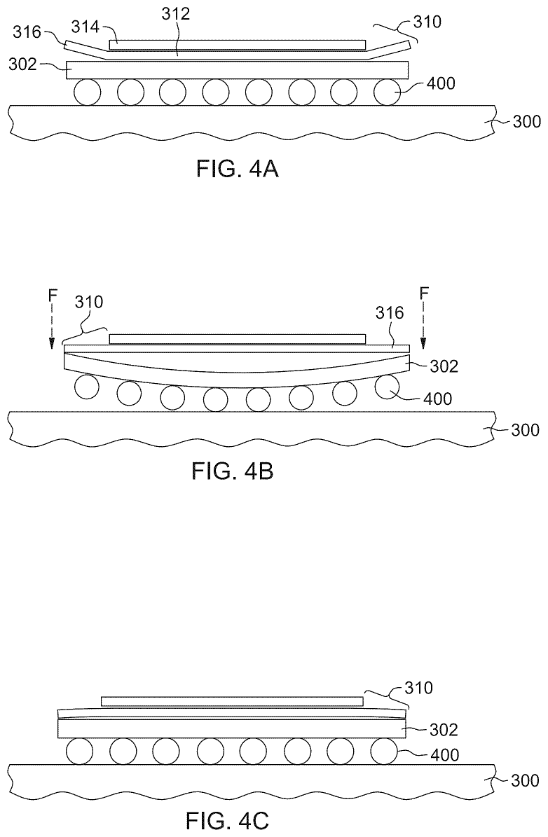

FIGS. 4A-4C illustrate operation of cover 310, and in particular, shape memory alloy tabs 316 of cover 310 during the circuit board reflow process. In FIG. 4A, an elevational view of the covered component of FIGS. 3A-3B is depicted, which includes a component 302 with a ball grid array 400 to electrically and mechanically couple the component to circuit board 300. In one or more embodiments, cover 310 includes a rigid structure 314 and shape memory alloy structure 312 attached together, and with the cover coupled, for instance via edge fasteners, to component 302. As discussed, shape memory alloy structure 312 includes tabs 316 which extend, for instance, at a desired angle at room temperature relative to an upper surface of component 302, that is, prior to the reflow process. Note that cover 310 can be obtained in a number of manners, including being fabricated from a shape memory alloy. Fabrication of the cover with the shape memory alloy structure can include forming the desired end shape at an elevated temperature, quenching the structure, and deforming the structure to a desired start shape at room temperature. In one or more embodiments, where the component 302 is a LGA socket, the standard LGA socket cover (e.g., see FIG. 1B) can be replaced for the reflow process by cover 310, which contains the shape memory alloy structure, and in particular, the shape memory alloy tabs.

During the reflow process, the corners of component 302 can curve inward, warping the outer corners of the component in a manner such as illustrated in FIG. 4B. Commensurate with the increase in temperature to facilitate the reflow process, the shape memory alloy structure, and in particular, the shape memory alloy tabs transition in a manner to facilitate inhibiting the warping of component 302 by applying a force in a direction counter to the warping. In the example of FIG. 4B, a force F is applied in a downward direction on the corners or edges of component 302 by the shape memory alloy transition. This force acts to mitigate and correct any lift off of solder connections 400 from the opposing surface of the circuit board. As the transition energy threshold (e.g., transition temperature) for the shape memory alloy material is reached, which occurs prior to peak reflow temperature, the shape memory alloy material returns to its original, cast shape, with the original shape being selected so that the shape memory alloy pushes against the warping corners of the component, forcing the component to return to a planar orientation and/or maintaining the corners in a planar orientation during the reflow process. The shape memory alloy material reaches full extension on the component using the affixed cover as the opposing force. In this manner, all solder connections 400 or joints are secured to the circuit board on cool down, as illustrated in FIG. 4C. Once reflow is complete, the cover can be removed and, in the case of a socket, replaced by the standard socket cover. In the case of the two-way effect design, the shape memory alloy structure returns to its compressed state once cooled. Those skilled in the art will note the particular shape memory alloy material, and size and thickness of the shape memory alloy material, can be selected to generate the desired downward force on the component edges or corners during the reflow process to inhibit the warping of the component during the reflow process, as disclosed herein.

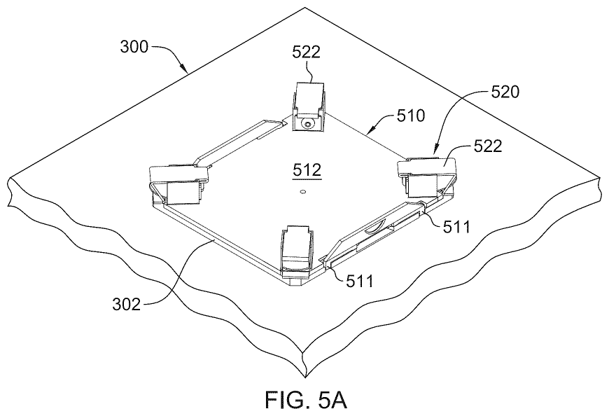

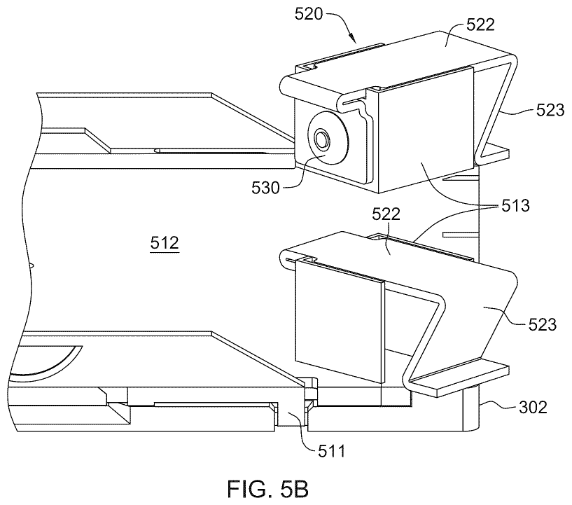

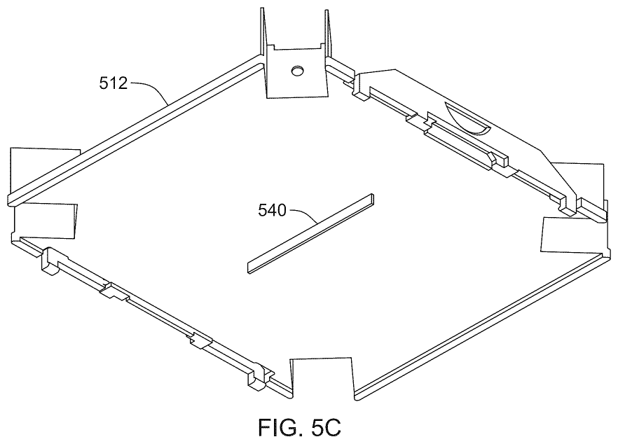

FIGS. 5A-5C depict one embodiment of a covered component on a circuit board 300, where the covered component includes a cover 510 with multiple independent shape memory alloy structures 520 configured to inhibit warping of a component 302 during a reflow process. In one or more embodiments, the shape memory alloy structures 520 are fabricated from a shape memory alloy (e.g., smart metal, memory metal, smart alloy, etc.) as described herein. For instance, in one or more embodiments, the shape memory alloy is a copper—aluminum—nickel or nickel titanium alloy, by way of example only. As noted herein, the shape memory alloy material can have different shape memory effects, including a one-way shape memory alloy effect or a two-way shape memory alloy effect, as described.

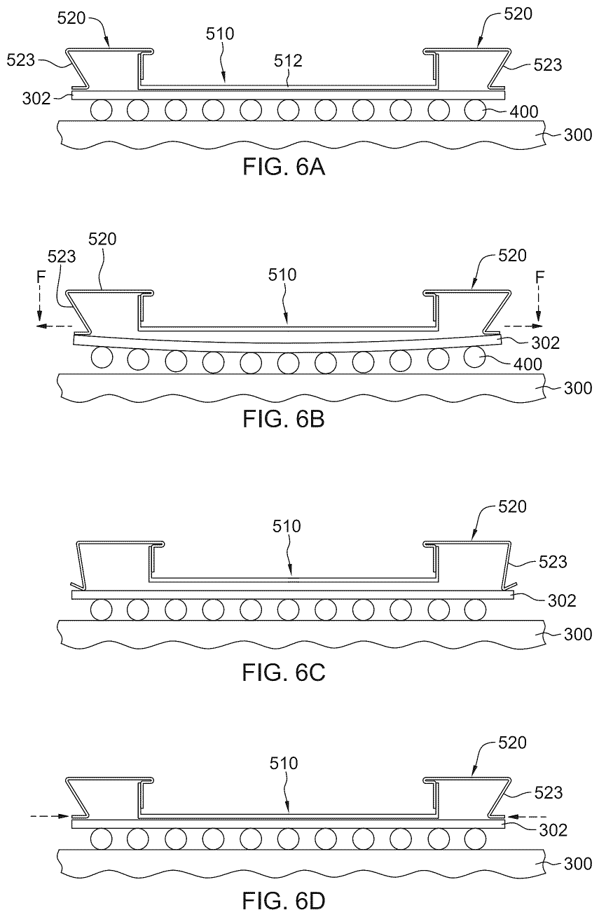

As noted with respect to the example of FIGS. 3A-3D, in one embodiment, component 302 can be a socket, such as a hybrid land grid array (LGA) socket connector, which in one embodiment includes a ball grid array 400 (FIGS. 6A-6D) connecting component 302 to circuit board 300, as well as, for instance, a land grid array on an upper surface of component 302, as described above. In embodiments, cover 510 is configured to couple, via multiple fasteners 511, to component 302 to fasten the cover to the component for the reflow process, as described herein. By way of example, fasteners 511 can be similar in design, construction, and operation to fasteners 106 described above in connection with FIGS. 1A-1C, and/or to fasteners 311 described above in connection with FIGS. 3A-3C. In embodiments, fasteners 511 are provided to couple or affix cover 510 to component 302 for the circuit board reflow process, as described herein.

In embodiments, cover 510 includes multiple shape memory alloy structures 520, each positioned over, and at, a respective corner of component 302, to inhibit warping of the component corner edges during the reflow process. In the embodiment depicted, cover 510 includes a rigid structure 512 with posts 513 or arms extending upward at the corners of the cover to accommodate the respective shape memory alloy structures 520. In one or more embodiments, the rigid structure 512 of cover 510 can be, for instance, a forged carbon, carbon-reinforced material, and/or a high performance thermoplastic material, such as a liquid crystal polymer (LCP) composite, by way of example. As illustrated in FIG. 5B, rivets 530 can be used for securing the respective shape memory alloy structures 520 to the respective posts of rigid structure 512, by way of example.

In the embodiment depicted, shape memory alloy structures 520 each include an upper base portion 522 from which extend down a respective spring tab 523, such as a respective Z-shaped tab, that is formed, or pre-formed, to extend down and, for instance, contact an upper surface of component 302 at room temperature and to extend outward and downward during the reflow process to apply force to the respective corners of the component 302 during circuit board reflow. Those skilled in the art will note that the configuration and size, including width and thickness, of the shape memory alloy structures can be selected to apply the desired force for a particular type of component of the circuit board. Further, note that, in one or more embodiments, rigid structure 512 can include a rib 540 extending from the rigid structure towards component 302 with the cover coupled to the component. FIG. 5C depicts one embodiment of rib 540 sized and configured to reside, for instance, between main contact arrays on the opposing surface of component 302 (e.g., a socket) with coupling of cover 510 to component 302 on a circuit board 300. Rib 540 can be sized and configured to inhibit a convex deformation of the component during the reflow process, in one or more embodiments.

FIGS. 6A-6D illustrates operation of cover 510, and in particular, operation of the shape memory alloy structures 520 during circuit board reflow. In FIGS. 6A-6D, an elevational view of the covered component of FIGS. 5A-5B is depicted, which as noted, includes a component 302 with a ball grid array 400 to electrically and mechanically couple component 302 to circuit board 300. Cover 510 includes a rigid structure 512, such as depicted in FIGS. 5A-5C, with multiple shape memory alloy structures 520 attached to the rigid structure over the corners of the component 302, in one or more embodiments.

In one or more embodiments, shape memory alloy structures 520 are configured as spring tabs 523, or Z-shaped tabs, which extend down close to and/or in contact with the respective corners or edges of component 302 at room temperature, that is, prior to the reflow process. Note that cover 510 can be obtained in any of a variety of manners, including, for instance, can be fabricated with the shape memory alloy structures and the rigid structure illustrated. Fabrication of cover 510 with the shape memory alloy structures 520 can include forming the desired end shape at an elevated temperature, quenching the structure, and deforming the structure into a desired start shape at room temperature. In one or more embodiments, where the component is a hybrid LGA socket, the standard LGA socket cover is replaced by cover 510, which contains the shape memory alloy structures, and in particular, shape memory alloy spring tabs such as depicted in FIGS. 5A-5B. During the reflow process, the corners of component 302 can attempt to curve inward, warping the outer corners of the component in a manner such as illustrated in FIG. 6B. Commensurate with the increase in temperature to facilitate the reflow process, the shape memory alloy structures, and in particular, the shape memory alloy spring tabs 523 transition in a manner to facilitate inhibiting the warping of component 302 by applying a force counter to the warping. In the example of FIG. 6B, a force F is applied in a downward direction on the corners or edges of component 302 as a result of the shape memory alloy transition. This force acts to mitigate and correct any liftoff of solder connections 400 from the opposing surface of the circuit board assembly. As the transition energy threshold (e.g., transition temperature) for the shape memory alloy is reached, which occurs prior to peak solder reflow temperature, the shape memory alloy material returns to its original, extended shape, with its original shape again being selected and configured so that the transitioning shape memory alloy pushes against the warping corners of the component 302, forcing the component to return to a planar orientation and/or maintaining the corners in a planar orientation during the reflow process, as illustrated in FIG. 6C. The shape memory alloy material reaches full extension on the component using the affixed cover as the opposing force. In this manner, all solder connections or joints are secured to the printed circuit board on cooldown, as illustrated in FIG. 6D. Once the reflow is complete, the cover can be removed and, in the case of a socket, can be replaced by the standard socket cover, if desired. In the case of the two-way effect design, the shape memory alloy structures return to their compressed state once cooled, and the cover is ready to be used again. Those skilled in the art will note that the particular shape memory alloy material, and configuration, size and thickness of the memory alloy can be selected to generate the desired downward force on the component edges and/or corners during the reflow process to inhibit the warping of the component during the reflow process. For instance, in one or more embodiments, the shape memory alloy spring tabs 523 can have a different spring tab configuration then the Z-shaped tabs illustrated, by way of example.

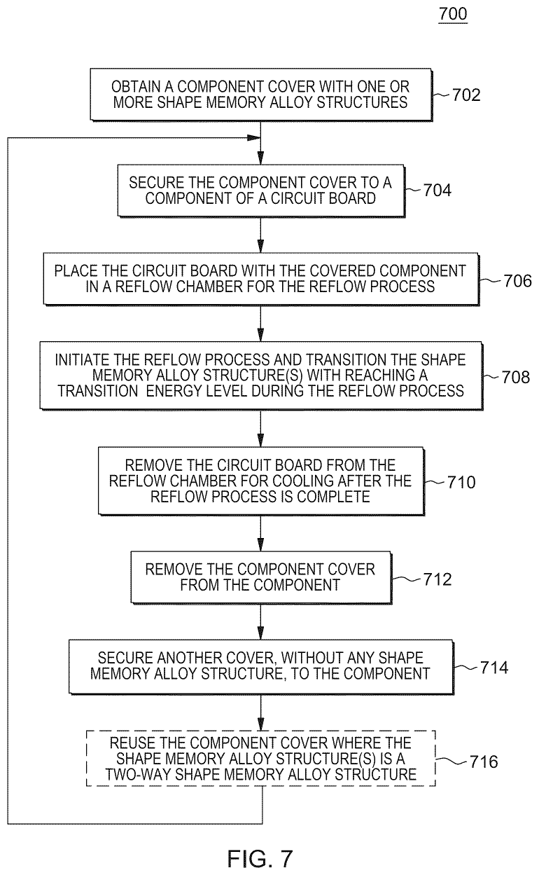

FIG. 7 depicts one embodiment of a circuit board reflow process using a covered component such as the covered component of FIGS. 3A-3D or the covered component of FIGS. 5A-5C, in accordance with one or more aspects of present disclosure. As illustrated, the reflow process 700 includes obtaining a component cover with one or more shape memory alloy structures 702, where the shape memory alloy structure(s) is configured to inhibit a warping of the component during the reflow process. The component cover is sized and configured to couple to a respective component to the circuit board. Note that, in this regard, obtaining the component cover can include fabricating, retrieving, receiving, or otherwise acquiring the component cover, which as noted, is configured and sized for the respective component (or component type) of the circuit board. In one or more embodiments, fabricating the component cover can include, for instance, preparing the shape memory alloy material by forming a desired end shape at an elevated temperature, quenching the shape memory alloy material, and deforming the material to the desired start shape at room temperature. As understood, in metallurgy, a shape memory alloy is, in one embodiment, an alloy that can be deformed when cold but returns to its pre-deformed shape when heated. In one or more embodiments, the cover is coupled (or secured) to the component 704. To couple the cover to the component of the circuit board, any conventional cover secured to the component is removed, and then replaced using the modified cover having the shape memory alloy structure(s). For instance, where the component is a hybrid land grid array socket, the standard LGA socket cover is replaced with a cover having the one or more shape memory alloy structures, such as described herein with reference to FIGS. 3A-6D.

As illustrated in FIG. 7, in one or more embodiments, the process also includes placing the circuit board with the covered component in a reflow oven for the reflow process 706 and initiating the reflow process 708. For instance, in one or more embodiments, the reflow process includes heating the circuit board with the covered component to a desired solder reflow temperature range. In one or more embodiments, the reflow temperature range is greater than the transition energy threshold (e.g., heat energy threshold or electromagnetic energy threshold) required to transition the shape memory alloy structure(s) of the cover. Upon the shape memory shape alloy structure(s) reaching the transition energy level during the reflow process, the shape memory alloy structure transitions and in so doing generates a force in a direction to inhibit the warping of the component. For instance, in one or more embodiments, the shape memory alloy structure is configured so that as the transition energy threshold is reached during the reflow process, the memory alloy generates a force (e.g., a pushing force) against the warping component, such as at the corners or edges of the warping component to force the component towards a planar configuration.

As illustrated in FIG. 7, in one embodiment, based on completing the reflow process, the circuit board is removed for cooling 710. In one or more embodiments, the cover is removed from the component after cooling of the circuit board 712, and, if desired, the conventional cover can be secured to the component 714 for further processing and/or handling of the circuit board. For instance, where the component is a hybrid land grid array socket, the standard LGA socket cover can be re-secured onto the socket. Where the shape memory alloy structure(s) is a two-way shape memory alloy structure, the cover can be reused 716 by coupling the cover to another component of another circuit board for another reflow process 716.

The terminology used herein is for the purpose of describing particular embodiments only and is not intended to be limiting of the invention. As used herein, the singular forms “a”, “an” and “the” are intended to include the plural forms as well, unless the context clearly indicates otherwise. It will be further understood that the terms “comprise” (and any form of comprise, such as “comprises” and “comprising”), “have” (and any form of have, such as “has” and “having”), “include” (and any form of include, such as “includes” and “including”), and “contain” (and any form contain, such as “contains” and “containing”) are open-ended linking verbs. As a result, a method or device that “comprises”, “has”, “includes” or “contains” one or more steps or elements possesses those one or more steps or elements, but is not limited to possessing only those one or more steps or elements. Likewise, a step of a method or an element of a device that “comprises”, “has”, “includes” or “contains” one or more features possesses those one or more features, but is not limited to possessing only those one or more features. Furthermore, a device or structure that is configured in a certain way is configured in at least that way, but may also be configured in ways that are not listed.

The corresponding structures, materials, acts, and equivalents of all means or step plus function elements in the claims below, if any, are intended to include any structure, material, or act for performing the function in combination with other claimed elements as specifically claimed. The description of one or more embodiments has been presented for purposes of illustration and description but is not intended to be exhaustive or limited to in the form disclosed. Many modifications and variations will be apparent to those of ordinary skill in the art. The embodiment was chosen and described in order to best explain various aspects and the practical application, and to enable others of ordinary skill in the art to understand various embodiments with various modifications as are suited to the particular use contemplated.

What is claimed is:

1. A method comprising:
obtaining a cover for a component of a circuit board, the cover including a shape memory alloy structure configured to inhibit warping of the component during a reflow process; and
coupling the cover to the component of the circuit board to form a covered component, wherein the coupling ensures that, with reaching of a transition energy threshold during the reflow process, the shape memory alloy structure of the cover generates, based on a shape memory alloy transition, a force in a direction to inhibit the warping of the component during the reflow process.

2. The method of claim 1, further comprising:
placing the circuit board with the covered component in an oven for the reflow process; and
initiating the reflow process, wherein when the transition energy threshold is reached during the reflow process, the shape memory alloy structure of the cover transitions and generates, based thereon, the force in the direction to inhibit the warping of the component.

3. The method of claim 2, further comprising:
based on completing the reflow process, removing the circuit board from the oven for cooling;
removing the cover from the component after cooling of the circuit board; and
coupling a standard cover to the component of the circuit board, the standard cover lacking the shape memory alloy structure.

4. The method of claim 1, wherein the shape memory alloy structure comprises multiple shape memory alloy tabs extending outward, the multiple shape memory alloy tabs being positioned to apply downward pressure to respective corners of the component based on reaching the transition energy threshold to inhibit the warping of the component during the reflow process.

5. The method of claim 4, wherein the shape memory alloy tabs comprise one-way shape memory alloy tabs.

6. The method of claim 4, wherein the shape memory alloy tabs comprise two-way shape memory alloy tabs, and the method further comprises:
removing the cover from the component based on completion of the reflow process; and
coupling the cover to another component to form another covered component, the coupling of the cover to the other component ensuring that with reaching of the transition energy threshold during another reflow process, the shape memory alloy structure of the cover generates, based on the shape memory alloy transition, the force in the direction to inhibit the warping of the other component during the other reflow process.

7. The method of claim 1, wherein the component comprises a socket and the cover further comprises a rigid structure attached to the shape memory alloy structure, the rigid structure including a rib sized and configured to reside between main contact arrays on an opposing surface of the socket with coupling of the cover to the socket of the circuit board, the rib to inhibit a convex deformation of the socket during the reflow process.

8. A method comprising:
obtaining a cover for a component of a circuit board, the cover including multiple shape memory alloy structures configured to inhibit warping of the component during a reflow process; and
coupling the cover to the component of the circuit board to form a covered component, wherein the coupling ensures that with reaching a transition energy threshold during the reflow process, the multiple shape memory alloy structures of the cover generate, based on a shape memory alloy transition, a force in a direction to inhibit the warping of the component during the reflow process.

9. The method of claim 8, further comprising:
placing the circuit board with the covered component in an oven for the reflow process; and
initiating the reflow process, wherein when the transition energy threshold is reached during the reflow process, the multiple shape memory alloy structures of the cover transition and generate, based thereon, the force in the direction to inhibit the warping of the component.

10. The method of claim 9, further comprising:
based on completing the reflow process, removing the circuit board from the oven for cooling;
removing the cover from the component after cooling of the circuit board; and
coupling a standard component cover to the component of the circuit board, the standard component cover lacking the shape memory alloy structures.

11. The method of claim 8, wherein the multiple shape memory alloy structures comprise multiple independent shape memory alloy spring tabs configured and positioned to apply downward pressure to corners of the component, based on reaching the transition energy threshold, to inhibit the warping of the component during the reflow process.

12. The method of claim 11, wherein the shape memory alloy spring tabs comprise one-way shape memory alloy spring tabs.

13. The method of claim 11, wherein the shape memory alloy spring tabs comprise two-way shape memory alloy spring tabs, and the method further comprises:
removing the cover from the component based on completion of the reflow process; and
coupling the cover to another component to form another covered component, the coupling of the cover to the other component ensuring that with reaching of the transition energy threshold during another reflow process, the shape memory alloy spring tabs of the cover generate, based on the shape memory alloy transition, the force in the direction to inhibit the warping of the other component during the other reflow process.

14. The method of claim 8, wherein the component comprises a socket and the shape memory alloy structures are attached to a rigid structure of the cover, the rigid structure including a rib sized and configured to reside between main contact arrays on an opposing surface of the socket with coupling of the cover to the socket of the circuit board, the rib to inhibit a convex deformation of the socket during the reflow process.

15. A component cover comprising:
a rigid structure;
a shape memory alloy structure attached to the rigid structure; and
wherein the shape memory alloy structure is configured to inhibit warping of a component of a circuit board during a reflow process, with the component cover coupled to the component, by generating based on a shape memory alloy transition with reaching of a transition energy threshold, a force in a direction to inhibit the warping of the component during the reflow process.

16. The component cover of claim 15, wherein the shape memory alloy structure comprises multiple shape memory alloy tabs extending outward, the multiple shape memory alloy tabs being positioned to apply downward pressure to respective corners of the component based on reaching the transition energy threshold to inhibit the warping of the component during the reflow process.

17. The component cover of claim 16, wherein the shape memory alloy tabs comprise one-way shape memory alloy tabs.

18. The component cover of claim 16, wherein the shape memory alloy tabs comprise two-way shape memory alloy tabs.

19. The component cover of claim 15, further comprising multiple shape memory alloy structures, the shape memory alloy structure being one shape memory alloy structure of the multiple shape alloy memory structures, and wherein the multiple shape memory alloy structures comprise multiple independent shape memory spring tabs configured and positioned to apply downward pressure to corners of the component, based on reaching the transition energy threshold, to inhibit the warping of the component during the reflow process.

20. The component cover of claim 15, wherein the component comprises a socket and the rigid structure further comprises a rib sized and configured to reside between main contact arrays on an opposing surface of the socket with coupling of the component cover to the socket of the circuit board, the rib to inhibit a convex deformation of the socket during the reflow process.
